(19) United States
(12) Patent Application Publication
(10) Pub. No.: US 2009/0236216 A1
(43) Pub. Date: Sep. 24, 2009

(54) METHOD OF MANUFACTURING THIN FILM MAGNETIC HEAD

(75) Inventors: Tomoka Aoki, Kawasaki (JP); Junji Sato, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/259,071

(22) Filed: Oct. 27, 2008

(30) Foreign Application Priority Data
Mar. 18, 2008 (JP) 2008-068700

(51) Int. Cl. C23C 14/34

(52) U.S. Cl. 204/192.1

(57) ABSTRACT

A method of manufacturing a thin film magnetic head is capable of forming a gap depth at high precision. The method includes: a step of forming, on a lower front end magnetic pole of a recording head unit that constructs the thin film magnetic head, a resist layer that has a shape where, in a cross section in a recording track direction and a head height direction, a length in the head height direction increases from a lower part of the resist layer toward an upper part; and a step of lifting off that forms a gap depth setting layer by sputtering on an insulating layer that is adjacent to the lower front end magnetic pole and on the resist layer and then carries out a lift off process that removes the resist layer and leaves the gap depth setting layer in a predetermined form.

### BACKGROUND OF THE INVENTION

1. Field of the Invention

The present invention relates to a method of manufacturing a thin film magnetic head and in more detail to a method of manufacturing a thin film magnetic head on which a recording head unit used in a storage apparatus such as a magnetic disk apparatus is formed.

2. Related Art

In recent years, there has been a tendency for the storage capacity of storage apparatuses such as magnetic disk apparatuses to increase remarkably. As a result of such increase, there has been demand for improved performance for recording media and for further improvements in the recording/reproducing characteristics of a magnetic head.

At present, heads that use MR (MagnetoResistance) elements or GMR (Giant MagnetoResistance) elements that can achieve a high reproduction output, and also heads that use TMR (Tunneling MagnetoResistance) elements that can achieve even higher reproduction sensitivity are being developed as reproduction head units. On the other hand, induction-type recording heads that use electromagnetic induction are also being developed as recording head units. For example, composite thin film magnetic heads where the reproduction head unit and the recording head unit described above are integrally formed are used in magnetic disk apparatuses.

Here, the method disclosed in Japanese Laid-Open Patent Publication No. 2007-172708 has been proposed as one example of a conventional method of manufacturing a thin film magnetic head (see FIG. 7). According to Japanese Laid-Open Patent Publication No. 2007-172708, the method includes steps of forming a GD setting layer 104 that sets a depth toward an inside from a medium facing surface of a non-magnetic layer 106 on a substrate that includes a lower core layer 102, forming a magnetic pole layer 113 constructed of a pair of magnetic pole layers 105, 107 with the non-magnetic layer 106 in between on the substrate, reducing the thickness of the GD setting layer 104 so that an upper surface of the GD setting layer 104 at the interface between the magnetic pole layer 113 and the GD setting layer 104 is positioned within the thickness of the non-magnetic layer 106, and reducing the width of the magnetic pole layer. By doing so, it is possible to provide a thin film magnetic head that can prevent noise from being generated during recording and can therefore record information properly.

### SUMMARY OF THE INVENTION

Here, a method of manufacturing a thin film magnetic head 250 that is an existing invention proposed by the applicant of the present invention is shown in FIGS. 8A to 8E. Here, the process that manufactures a recording head unit 211 will be described in particular.

First, as shown in FIG. 8A, a coil lower insulating layer 217 is formed on a lower magnetic pole 201. Next, after a front portion 201a of the lower magnetic pole, a rear portion 201c of the lower magnetic pole, a coil layer 202, and an inter-coil insulating layer 218 have been formed, the upper surfaces thereof are smoothed by lapping so as to become continuous and flush. After this, a lower front end magnetic pole 201b is formed on the front portion 201a of the lower magnetic pole and a lower rear end magnetic pole 201d is formed on the rear portion 201c of the lower magnetic pole.

In addition, an insulating layer 203 is formed on the coil layer 202 and the inter-coil insulating layer 218 so as to be adjacent to the lower front end magnetic pole 201b and the lower rear end magnetic pole 201d.

After this, a gap layer 204 is formed by sputtering on the insulating layer 203, the lower front end magnetic pole 201b, and the lower rear end magnetic pole 201d.

Next, a resist layer 205′ is formed on the gap layer 204 using a resist material (see FIG. 8B) and after this, a hard bake process is carried out on the resist layer 205′.

This hard bake process will differ according to the thickness and the like of the resist layer 205′ but as one example is carried out for several hours at a high temperature of over 200° C. In this process, end portions of the resist layer 205′ will deform while shrinking due to the heat, which results in a resist layer 205 being formed with sloped surfaces that make a predetermined angle β (called the “apex angle”) to the upper surface of the gap layer 44 (see FIG. 8C). Here, the angle β is a predetermined angle that depends on the material and initial form of the resist and on the conditions of the hard bake process.

In this case, the length in the head height direction indicated as “GD” in FIG. 8C is the “gap depth”. As described above, the disposed position, thickness and the like of the resist layer 205′ are determined in view of the end portions of the resist layer 205′ shrinking and deforming during the hard bake process so that optimal values are achieved for both P and GD.

After this, as shown in FIG. 8D, a mask 231 is formed of a resist material on the gap layer 204 and the resist layer 205, and unnecessary parts of the gap layer 204 are removed by dry etching.

In addition, as shown in FIG. 8E, after the plating base 232 has been applied, a resist pattern 233 is formed and then an upper magnetic pole 206 is formed by building up to a predetermined thickness by electroplating. Note that reference numeral 207 designates an air bearing surface (i.e., a surface that faces the medium).

The form and precision of GD and β greatly affect the recording characteristics of the recording head unit, especially in a horizontal recording-type thin film magnetic head. However, in the method of manufacturing described above, it is extremely difficult to independently control GD and β with high precision. The reason for this is that when GD changes, the apex angle β simultaneously changes. That is, it is difficult to carry out manufacturing with little fluctuation in GD and β, resulting in the problem of fluctuations in the recording characteristics of the recording head unit.

On the other hand, during the manufacturing process of a thin film magnetic head, since the use of RIE (Reactive Ion Etching) can lead to an increase in the number of processing steps, whenever possible, it is preferable to use a method of manufacturing that does not depend on an RIE process.

The present invention was conceived in view of the problem described above, and it is an object of the present invention to provide a method of manufacturing a thin film magnetic head that is capable of forming a gap depth at high precision without fluctuations and without a large increase in the number of manufacturing steps.

To achieve the stated object, a method of manufacturing a thin film magnetic head according to the present invention includes: a step of forming, on a lower front end magnetic pole of a recording head unit that constructs the thin film magnetic head, a resist layer that has a shape where, in a cross section in a recording track direction and a head height direction, a length in the head height direction increases from a lower part of the resist layer toward an upper part; a step of lifting off that forms a gap depth setting layer by sputtering on an insulating layer that is adjacent to the lower front end magnetic pole and on the resist layer and then carries out a lift off process that removes the resist layer and leaves the gap depth setting layer in a predetermined form; a step of forming a gap layer by sputtering on the lower front end magnetic pole and the gap depth setting layer; and a step of forming an upper magnetic pole on the gap layer.

According to this method, it is possible to deposit the gap depth setting layer and the gap layer with high precision and therefore it is possible to suppress fluctuations in the gap depth (GD).

In a cross-sectional form of the gap depth setting layer in the recording track direction and the head height direction, a lower end portion on an air-bearing surface side may include an inclined surface with a predetermined angle.

By doing so, it is possible to stabilize the film thickness of the gap layer that will be formed by sputtering on the gap depth setting layer. In addition, by optimizing the angle of the inclined surface, it is possible to make the recording characteristics more optimal.

Also, the gap depth setting layer may be formed using an inorganic material. In particular, Al₂O₃, SiO₂, and SiC can be favorably used as the inorganic material.

By doing so, it becomes possible to form the gap depth setting layer by sputtering.

Note that the method of manufacturing a thin film magnetic head according to the present invention can be favorably applied to manufacturing a horizontal recording-type thin film magnetic head.

According to the present invention, when manufacturing a thin film magnetic head, it is possible to form the GD (gap depth) of the recording head unit and the periphery thereof with high precision while suppressing an increase in the number of manufacturing steps.

### BRIEF DESCRIPTION OF THE DRAWINGS

FIG. 1 is a schematic diagram showing one example construction of a thin film magnetic head manufactured according to a method of manufacturing a thin film magnetic head according to an embodiment of the present invention;

FIGS. 2A to 2F are diagrams useful in explaining the method of manufacturing the thin film magnetic head according to an embodiment of the present invention;

FIGS. 3A and 3B are enlarged views of a resist layer and a periphery thereof that are formed in an intermediate process in the method of manufacturing according to an embodiment of the present invention;

FIGS. 4A and 4B are enlarged views of a resist layer and a periphery thereof (in a state immediately before lifting off) that are formed in an intermediate process in the method of manufacturing according to an embodiment of the present invention;

FIG. 5 is an enlarged view of the periphery of a gap depth setting layer that is formed by an intermediate process in the method of manufacturing according to an embodiment of the present invention;

FIGS. 6A to 6C are diagrams useful in explaining a method of manufacturing a thin film magnetic head according to an embodiment of the present invention;

FIG. 7 is a diagram useful in explaining an example of a method of manufacturing a thin film magnetic head according to the conventional art; and

FIGS. 8A to 8E are diagrams that are useful in explaining another example of a method of manufacturing a thin film magnetic head according to the conventional art.

### DESCRIPTION OF THE PREFERRED EMBODIMENTS

Preferred embodiments of the present invention will now be described in detail with reference to the attached drawings.

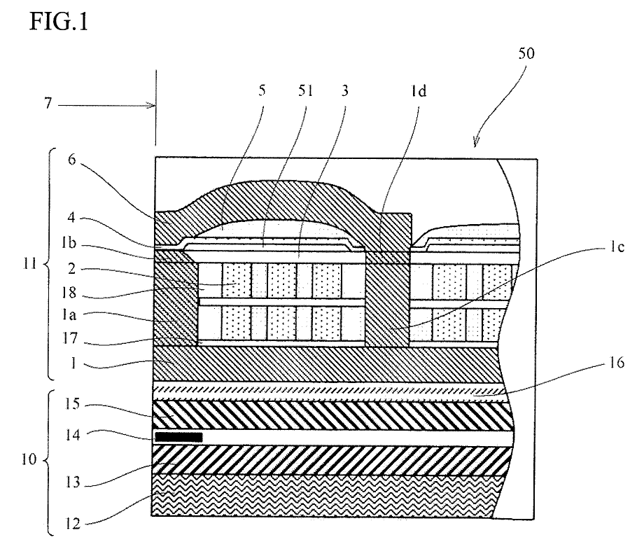

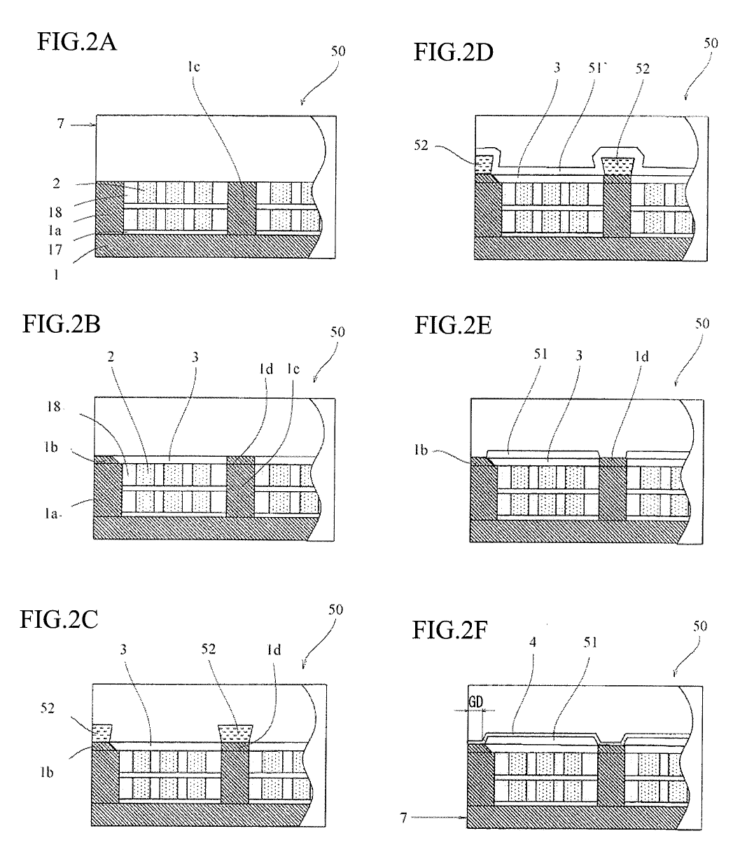

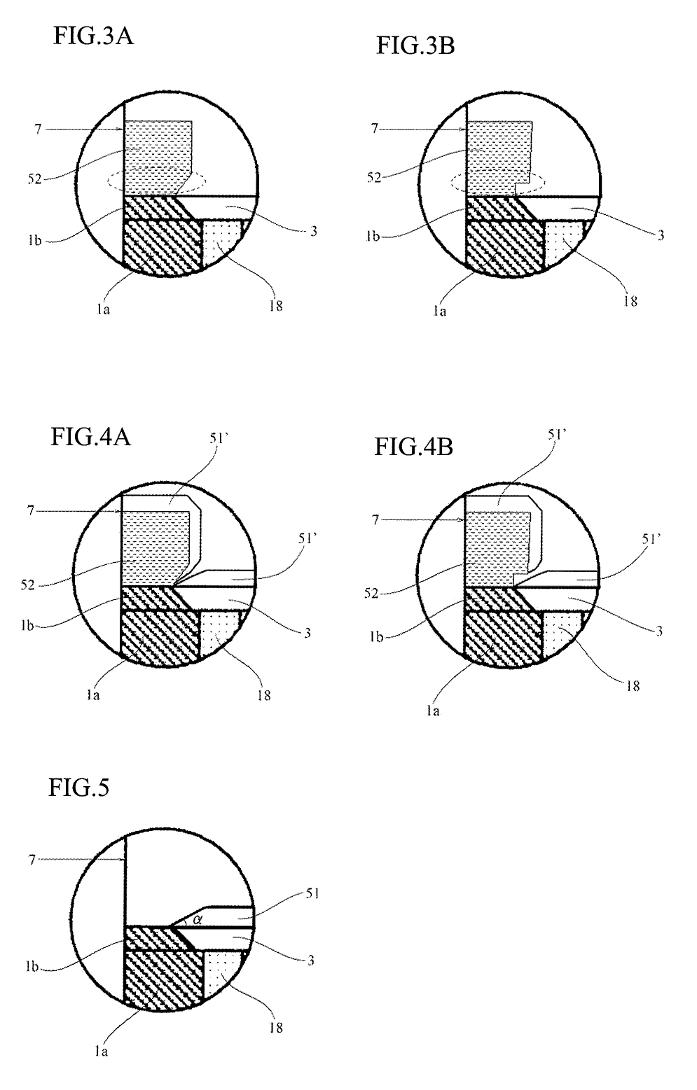

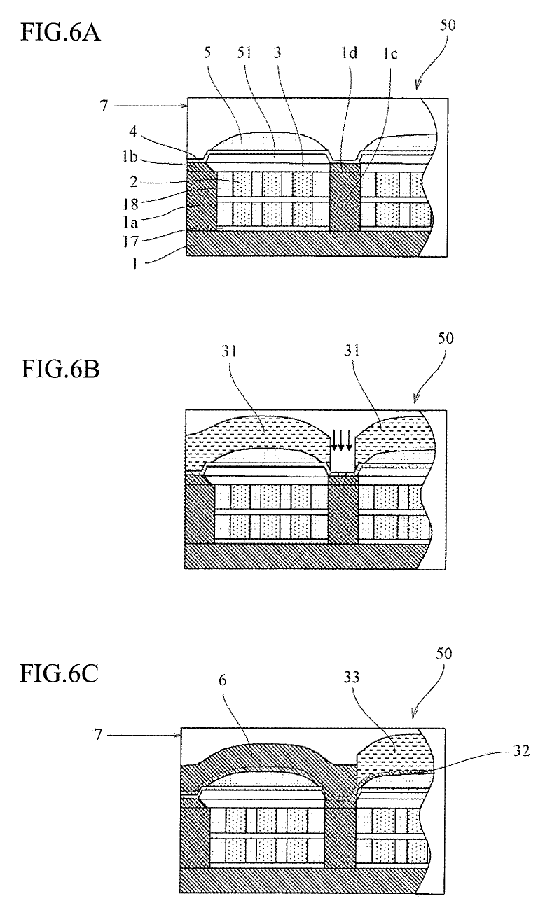

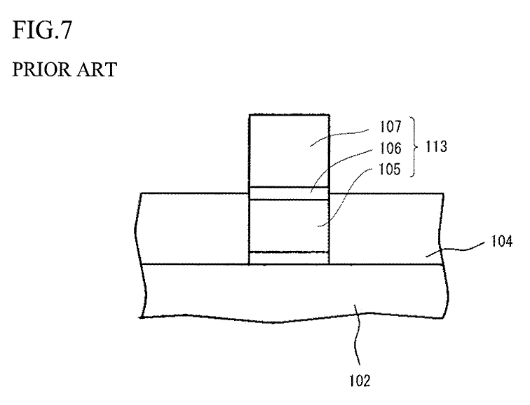

FIG. 1 is a schematic diagram showing one example construction of a thin film magnetic head 50 manufactured according to a method of manufacturing a thin film magnetic head according to an embodiment of the present invention. FIGS. 2A to 2F are diagrams useful in explaining the method of manufacturing the thin film magnetic head 50. FIGS. 3A and 3B and FIGS. 4A and 4B are enlarged views of a periphery of a resist layer 52 formed in an intermediate process in the method of manufacturing the thin film magnetic head 50 (where FIGS. 4A and 4B show a state immediately before lifting off). Note that FIGS. 3A and 4A show an example of a case where an image reversal resist is used and FIGS. 3B and 4B show an example of a case where a bilayer resist is used. FIG. 5 is an enlargement of the periphery of a gap depth setting layer 51 formed by an intermediate process in the method of manufacturing the thin film magnetic head 50. FIGS. 6A to 6C are enlargements that are useful in explaining a method of manufacturing the thin film magnetic head 50.

The thin film magnetic head 50 according to the present invention is a thin film magnetic head with a recording head unit 11 that writes a magnetic signal onto a magnetic recording medium such as a hard disk. As one example, the recording head unit 11 is laminated on a reproduction head unit 10, and recording and reproduction are carried out by causing a head slider to float above a rotating recording disk (magnetic recording medium).

The construction of the thin film magnetic head 50 will now be described for an example of a horizontal recording-type thin film magnetic head. However, this is merely one example, and the present invention is not limited to this construction.

As shown in FIG. 1, the thin film magnetic head 50 includes the reproduction head unit 10 and the recording head unit 11. Reference numeral 7 designates an air-bearing surface, that is, a surface that faces a medium.

In more detail, the reproduction head unit 10 has a multilayer construction where a lower shield layer 13, a magnetoresistance-type reproduction element 14, and an upper shield layer 15 are laminated on a substrate 12. As one example, the substrate 12 is constructed using an insulating material such as Al₂O₃—TiC.

Here, the magnetoresistance-type reproduction element 14 is constructed using a TMR element or a GMR element, for example. It is possible to use a variety of constructions as the film construction of such TMR element or GMR element. Note that as the GMR element, a CPP-GMR (Current Perpendicular to Plane-GMR) element or a CIP-GMR (Current In Plane-GMR) element may be used.

The lower shield layer 13 is constructed using NiFe that is a magnetic material (in more detail, a soft magnetic material). In the same way as the lower shield layer 13, the upper shield layer 15 is constructed using a magnetic material (in more detail, a soft magnetic material) such as NiFe.

Note that when a TMR element or a CPP-GMR (Current Perpendicular to Plane-GMR) element is used as the magnetoresistance-type reproduction element 14, the lower shield layer 13 and the upper shield layer 15 can also serve as the electric poles of such element, but when a CIP-GMR (Current In Plane-GMR) element is used, the lower shield layer 13 and the upper shield layer 15 cannot serve as the electric poles of the element.

In the present embodiment, a magnetic separation layer 16 composed of an insulating material is provided on the upper shield layer 15 and the recording head unit 11 is then provided on top of the magnetic separation layer 16.

In more detail, the construction of the recording head unit 11 includes a lower magnetic pole 1 composed of a magnetic material such as permalloy. A front portion 1a of the lower electrode, a rear portion 1c of the lower electrode, and a coil lower insulating layer 17 are provided on the lower magnetic pole 1. As one example, the coil lower insulating layer 17 is constructed of an insulating material such as Al₂O₃.

Coil layers 2 are provided with a predetermined interval in between on the coil lower insulating layer 17. As one example, the coil layers 2 are formed as flat spirals using copper as a conductive material with low electrical resistance. Inter-coil insulating layers 18 are provided between the windings of the coil layers 2. As one example, the inter-coil insulating layers 18 are composed of a resist material or an insulating material such as Al₂O₃. Note that the present invention is an example where the coil layers 2 are composed of two layers.

An insulating layer 3 is provided above the coil layers 2 and the inter-coil insulating layers 18. As one example, the insulating layer 3 is composed of an insulating material such as Al₂O₃.

In the present embodiment, the gap depth setting layer 51 and part of a gap layer 4 are provided above the insulating layer 3 and another part of the gap layer 4 is provided above a lower front end magnetic pole 1b. The materials that compose the gap depth setting layer 51 and the gap layer 4 are described in detail later in the explanation of the method of manufacturing.

An upper magnetic pole build up layer 5 is provided on part of the gap layer 4 and an upper magnetic pole 6 is provided on the upper magnetic pole build up layer 5 and the gap layer 4. As one example, the upper magnetic pole 6 is composed of a magnetic material such as permalloy.

Next, a method of manufacturing the thin film magnetic head 50 according to the present embodiment will be described with reference to the drawings.

First, after the reproduction head unit 10 has been formed, the magnetic separation layer 16 is provided and the recording head unit 11 with the construction described above is formed thereon. Here, FIG. 2A shows a state where the coil layers 2, the inter-coil insulating layers 18, and the front portion 1a of the lower magnetic pole and the rear portion 1c of the lower magnetic pole have been formed and then the upper surfaces thereof have been smoothed by lapping so as to become continuous and flush.

Next, as shown in FIG. 2B, the lower front end magnetic pole 1b is formed on the front portion 1a of the lower magnetic pole and the lower rear end magnetic pole 1d is formed on the rear portion 1c of the lower magnetic pole. Both the lower front end magnetic pole 1b and the magnetic poles 1b and the lower rear end magnetic pole 1d are formed by electroplating in the present embodiment.

In addition, the insulating layer 3 is formed by sputtering on the coil layers 2 and the inter-coil insulating layers 18 so as to be adjacent to the lower front end magnetic pole 1b and the lower rear end magnetic pole 1d.

At this time, the insulating layer 3 is formed with a length in the head height direction that is capable of completely covering the coil layers 2. Here, the gap depth setting layer 51 and the gap layer 4, described later, that are provided on the insulating layer 3 are also formed with a sufficient length in the head height direction so as to completely cover the coil layers 2 because this is essential for achieving stable recording characteristics in a thin film magnetic head with the present construction.

Note that as desired the upper surface of the insulating layer 3 and the upper surfaces of the lower front end magnetic pole 1b and the lower rear end magnetic pole 1d that are adjacent to the insulating layer 3 may also be smoothed by lapping so as to become continuous and flush.

Next, the gap depth setting layer 51 is formed by a lift off process.

First, as shown in FIG. 2C, the resist layer 52 is formed on the lower front end magnetic pole 1b and the lower rear end magnetic pole 1d. In particular, as shown by the partial enlargements in FIGS. 3A and 3B, a cross section of the resist layer 52 in the head height direction and recording track direction is formed in a shape where the length in the head height direction increases from the lower portion of the resist layer 52 toward an upper portion (the circle drawn using a broken line in FIGS. 3A and 3B). Note that FIG. 3A shows an example construction for the case where an image reversal resist is used and FIG. 3B shows an example construction for the case where a bilayer resist is used.

After this, as shown in FIG. 2D, the material that composes the gap depth setting layer 51 is deposited by sputtering on the insulating layer 3 and the resist layer 52 (this material is designated by reference numeral 51′ in FIG. 2D). Partial enlargements of this state are shown in FIG. 4A (that corresponds to FIG. 3A) and in FIG. 4B (that corresponds to FIG. 3B). In the present embodiment, an inorganic material such as Al₂O₃, SiO₂, or SiC is used as the material that composes the gap depth setting layer 51. Here, the inorganic material is not limited to Al₂O₃, SiO₂, and SiC, but it is essential that the material be capable of being deposited by sputtering. The reason for this is that since the gap depth setting layer 51 is a base layer for the gap layer 4 that will be formed by sputtering on the gap depth setting layer 51, to deposit the gap layer 4 with high precision, the gap depth setting layer 51 also has to be deposited with high precision. However by using sputtering, it is possible to control the film thickness with far higher precision than when the layer is formed by plating.

After this, the unnecessary parts are removed from the construction of the gap depth setting layer 51 together with the resist layer 52 to form the gap depth setting layer 51 as intended. This is shown in FIG. 2E.

At this time, as shown in the partial enlargement in FIG. 5, the gap depth setting layer 51 that forms the lower layer for the gap layer 4 is formed in a shape that has an inclined surface whose front end on the air bearing surface side makes a predetermined angle α. This will be described in detail later. This angle α is the “apex angle”, and this angle is defined by the material and form of the resist layer 52, the thickness of the gap depth setting layer 51, and the like (see FIGS. 3A, 3B, 4A, and 4B).

Note that when SiC is used as the material that constructs the gap depth setting layer 51, compared to when Al₂O₃ or SiO₂ is used, it is possible to achieve a low coefficient of thermal expansion. That is, it is possible to achieve an effect of reducing element protrusion in keeping with the film thickness.

Next, as shown in FIG. 2F, the gap layer 4 is formed on the gap depth setting layer 51, the lower front end magnetic pole 1b, and the lower rear end magnetic pole 1d. In the present embodiment, an insulating material such as SiO₂ is used as the gap layer 4 which is formed by sputtering.

Here, it is essential that the gap layer 4 be formed by sputtering. Sputtering is used since it is possible to control the film thickness with far higher precision compared to when the gap layer 4 is formed by plating. That is, it is possible to control the GD (gap depth) and form (i.e., film thickness) with high precision, and in particular, it is possible to carry out control over the form of the magnetic pole in the periphery of the so-called write gap both easily and with high precision.

In addition, regarding the gap depth setting layer 51 that is the lower layer for the gap layer 4 that is to be formed by sputtering, the front end on the air bearing surface 7-side is formed so as to have an inclined surface with the predetermined angle α. More specifically, although the angle will differ according to the construction and composite materials of the magnetic pole as a whole, in the present embodiment, a gentle angle of around 10[°]≦α≦30[°] is favorable from the viewpoints of optimizing the recording characteristics and stably forming the upper layer (i.e., the gap layer 4) with the desired film thickness.

Here, as described earlier, the angle α is determined by the material and form of the resist layer 52, the film thickness of the gap depth setting layer 51, and the like. However, by using the lift-off process that is characteristic to the present embodiment, it is possible to form the desired gentle angle both easily and with high precision.

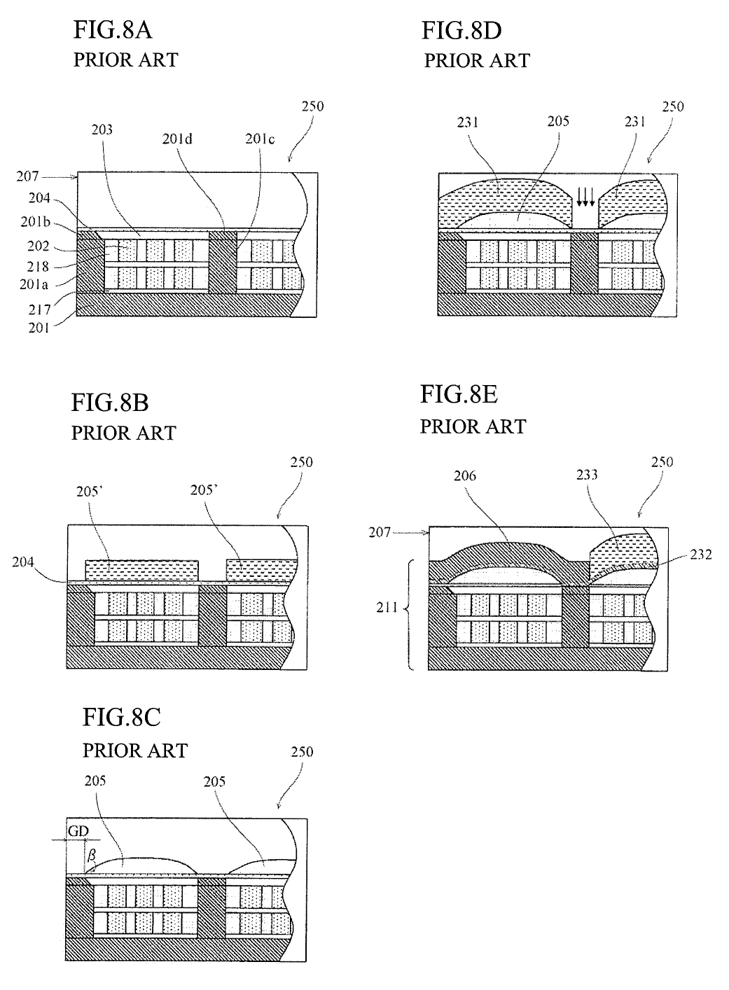

Therefore, according to the method described above, the size of the GD (gap depth) can be set by the disposed position and film thickness of the gap depth setting layer 51 and the film thickness of the gap layer 4 that can be formed with high precision. Also, since there is no hard bake process for the resist material in the GD setting layer forming process as in the conventional method shown in FIG. 8, the GD will not be affected by thermal contraction, which means that fluctuations in the GD can be greatly reduced and the GD can instead be set with high precision. In addition, by not using a RIE process in the manufacturing process, it is possible to suppress increases in the number of processing steps, so that it becomes possible to manufacture a thin film magnetic head in a short time and at low cost.

Next, the processes up to the formation of the upper magnetic pole 6 will be described with reference to FIGS. 6A to 6C.

FIG. 6A shows a state where a hard bake process has been carried out after the upper magnetic pole build up layer 5 has been formed on part of the gap layer 4 using a resist material.

After this, as shown in FIG. 6B, a mask 31 is formed using a resist material on the gap layer 4 and the upper magnetic pole build up layer 5, and then dry etching is carried out to remove unnecessary parts of the gap layer 4.

In addition, as shown in FIG. 6C, after a plating base 32 has been applied, a resist pattern 33 is formed and the upper magnetic pole 6 is formed by building up to a predetermined thickness by electroplating.

As described above, according to the method of manufacturing a thin film magnetic head according to the above embodiment, compared to the conventional method, it is possible to form the GD (gap depth) of the recording head unit with high precision while suppressing increases in the number of manufacturing steps. As a result, it is possible to manufacture a thin film magnetic head with highly precise recording characteristics in a short time and at low cost.

Note that although an example of a horizontal recording thin film magnetic head with a construction where the write gap is formed on an upper layer out of two coil layers has been described, the present invention is not limited to this.

What is claimed is:

1. A method of manufacturing a thin film magnetic head comprising:
a step of forming, on a lower front end magnetic pole of a recording head unit that constructs the thin film magnetic head, a resist layer that has a shape where, in a cross section in a recording track direction and a head height direction, a length in the head height direction increases from a lower part of the resist layer toward an upper part;
a step of lifting off that forms a gap depth setting layer by sputtering on an insulating layer that is adjacent to the lower front end magnetic pole and on the resist layer and then carries out a lift off process that removes the resist layer and leaves the gap depth setting layer in a predetermined form;
a step of forming a gap layer by sputtering on the lower front end magnetic pole and the gap depth setting layer; and
a step of forming an upper magnetic pole on the gap layer.

2. A method of manufacturing a thin film magnetic head according to claim 1,
wherein in a cross-sectional form of the gap depth setting layer in the recording track direction and the head height direction, a lower end portion on an air-bearing surface side includes an inclined surface with a predetermined angle.

3. A method of manufacturing a thin film magnetic head according to claim 1,
wherein the gap depth setting layer is formed using an inorganic material.

4. A method of manufacturing a thin film magnetic head according to claim 2,
wherein the gap depth setting layer is formed using an inorganic material.

5. A method of manufacturing a thin film magnetic head according to claim 3,
wherein Al₂O₃, SiO₂, and/or SiC is used as the inorganic material gap depth setting layer.

6. A method of manufacturing a thin film magnetic head according to claim 4,
wherein Al₂O₃, SiO₂, and/or SiC is used as the inorganic material gap depth setting layer.

7. A method of manufacturing a thin film magnetic head according to claim 1,
wherein the thin film magnetic head is a horizontal recording-type thin film magnetic head.

8. A method of manufacturing a thin film magnetic head according to claim 2,
wherein the thin film magnetic head is a horizontal recording-type thin film magnetic head.

9. A method of manufacturing a thin film magnetic head according to claim 3,
wherein the thin film magnetic head is a horizontal recording-type thin film magnetic head.

10. A method of manufacturing a thin film magnetic head according to claim 4,
wherein the thin film magnetic head is a horizontal recording-type thin film magnetic head.

11. A method of manufacturing a thin film magnetic head according to claim 5,
wherein the thin film magnetic head is a horizontal recording-type thin film magnetic head.

12. A method of manufacturing a thin film magnetic head according to claim 6,
wherein the thin film magnetic head is a horizontal recording-type thin film magnetic head.
